(19) United States
(12) Patent Application Publication
(10) Pub. No.: US 2008/0079086 A1
(43) Pub. Date: Apr. 3, 2008

(54) SEMICONDUCTOR DEVICE AND METHOD OF MANUFACTURING THE SAME

(76) Inventors: Hyung-suk Jung, Suwon-si (KR); Jong-ho Lee, Suwon-si (KR); Sung-kee Han, Seongnam-si (KR); Ho Lee, Cheonan-si (KR); Ha-jin Lim, Seoul (KR)

Correspondence Address: F. CHAU & ASSOCIATES, LLC, 130 WOODBURY ROAD, WOODBURY, NY, 11797, US

(21) Appl. No.: 11/831,069

(22) Filed: Jul. 31, 2007

(30) Foreign Application Priority Data
Aug. 10, 2006 (KR) 10-2006-0075816

(51) Int. Cl. H01L 21/336; H01L 27/085

(52) U.S. Cl. 257/369; 438/217; 257/E21.409; 257/E27.067

(57) ABSTRACT

A semiconductor device and a method of manufacturing the semiconductor device, in which the semiconductor device includes a semiconductor substrate in which PMOS transistor regions and NMOS transistor regions are formed, a PMOS transistor including P-type source and drain regions and a gate electrode, and an NMOS transistor formed on an Si channel region between N-type source and drain regions. The PMOS transistor is formed in each PMOS transistor region, and the gate electrode is formed on a high-dielectric gate insulating film formed on an SiGe channel region between the P-type source and drain regions. Further, the NMOS transistor includes a high-dielectric gate insulating film and a gate electrode formed on the gate insulating film, and the NMOS transistor is formed in each NMOS transistor region.

### CROSS REFERENCE TO RELATED APPLICATION

This application claims priority from Korean Patent Application No. 10-2006-0075816 filed on Aug. 10, 2006 in the Korean Intellectual Property Office, the disclosure of which is incorporated herein by reference in its entirety,

### BACKGROUND OF THE INVENTION

1. Technical Field

The present disclosure relates to a semiconductor device and a method of manufacturing the semiconductor device and, more particularly, to a semiconductor device that includes PMOS transistors and NMOS transistors having improved performance and a method of manufacturing the semiconductor device.

2. Discussion of Related Art

As integrated circuits have been developed, the size of the device has become smaller so as to achieve a high degree of integration and to achieve a high performance. In particular, as the thickness of a gate insulating film is reduced, driving current used to drive an electronic device is increased. Accordingly, the gate insulating film is formed to have a thickness as thin as possible. For this reason, the formation of a gate insulating film, which is very thin and has high reliability and few defects, becomes important to improve the performance of the device.

A silicon thermal oxide film is stable against a silicon substrate provided below the silicon thermal oxide film, and a method of forming the silicon thermal oxide film is relatively simple. For this reason, the thermal oxide film, that is, a silicon oxide film, has been used as a gate insulating film for several years.

The silicon oxide film, however, has a low dielectric constant of about 3.9. For this reason, there is a limitation in reducing the thickness of the gate insulating film formed of the silicon oxide film, and it is more difficult to reduce the thickness of the silicon oxide film due to gate leakage current flowing in the gate insulating film that is formed of a thin silicon oxide film.

Accordingly, high-dielectric films (having a high k), which include a single metal oxide film such as a hafnium oxide film or a zirconium oxide film, a metal silicate such as a hafnium silicate or zirconium silicate, and an aluminate such as hafnium aluminum oxide, have been investigated as a substitute for a dielectric film that has a greater thickness than that of the silicon oxide film but can improve the performance of the device.

The threshold voltage of the PMOS device when a hafnium or zirconium-based dielectric film of the high-dielectric films is applied to a PMOS device, however, is larger by 0.3 to 0.6 V than that of the PMOS device when silicon oxynitride (SiON) of the dielectric film is applied to the PMOS device. Considering that a margin capable of being adjusted by channel engineering is 0.1 to 0.2 V, when the high-dielectric film is applied to the current processes, there is a limitation in adjusting the threshold voltage at a desired level.

In addition, when a polysilicon gate electrode is directly formed on the high-dielectric film, there is a problem in that gate depletion occurs and positive bias temperature instability (PBTI) is intensified in the case of the NMOS device.

For this reason, there is a demand for a semiconductor device in which a device characteristic such as a threshold voltage is excellent and a PBTI characteristic is not intensified, so as to be suitable for a transistor having high reliability.

### SUMMARY OF THE INVENTION

Exemplary embodiments of the present invention provide a semiconductor device that has an improved characteristic and reliability.

Exemplary embodiments of the present invention also provide a method of manufacturing the above-mentioned semiconductor device.

Exemplary embodiments of the present invention are not limited to those mentioned above, and other exemplary embodiments of the present invention will be understood by those of ordinary skill in the art through the following description.

According to an exemplary embodiment of the present invention, a semiconductor device includes a semiconductor substrate in which PMOS transistor regions and NMOS transistor regions are formed, a PMOS transistor including P-type source and drain regions and a gate electrode, and an NMOS transistor formed on an SiGe channel region between N-type source and drain regions. The PMOS transistor is formed in each PMOS transistor region, and the gate electrode is formed on a high-dielectric gate insulating film formed on an SiGe channel region between the P-type source and drain regions. Further, the NMOS transistor includes a high-dielectric gate insulating film and a gate electrode formed on the gate insulating film, and the NMOS transistor is formed in each NMOS transistor region.

In accordance with another exemplary embodiment of the present invention, a method of manufacturing a semiconductor device includes providing a semiconductor substrate in which PMOS transistor regions and NMOS transistor regions are formed, selectively forming an SiGe channel region in each PMOS transistor region, forming a high-dielectric gate insulating film on the SiGe channel region corresponding to the PMOS transistor region and on the semiconductor substrate corresponding to the PMOS transistor region, forming a PMOS transistor, which includes a gate electrode and P-type source and drain regions, on the SiGe channel region corresponding to the PMOS transistor region, and forming an NMOS transistor, which includes a gate electrode and N-type source and drain regions, on an Si channel region corresponding to the NMOS transistor region.

According to an exemplary embodiment of the present invention, a method of manufacturing a semiconductor device includes providing a semiconductor substrate in which PMOS transistor regions and NMOS transistor regions are defined by element isolation films, forming an epitaxial blocking film, which has an etching selectivity different from that of the element isolation film, on the semiconductor substrate, selectively removing the epitaxial blocking film formed in the PMOS transistor region so that the epitaxial blocking film remains in only the NMOS transistor region, forming an SiGe channel region on the PMOS transistor region by an SiGe epitaxy process, removing the remaining epitaxial blocking film so as to expose the semiconductor substrate corresponding to the NMOS transistor region, forming a high-dielectric gate insulating film on the Si capping film of the PMOS transistor region and on the semiconductor substrate corresponding to the PMOS transistor region, forming a PMOS transistor, which includes a gate electrode and P-type source and drain regions, on the SiGe channel region corresponding to the PMOS transistor region, and firming an NMOS transistor, which includes a gate electrode and N-type source and drain regions, on an Si channel region corresponding to the NMOS transistor region.

Details of exemplary embodiments are included in the detailed description and drawings.

### BRIEF DESCRIPTION OF THE DRAWINGS

Exemplary embodiments of the present invention will be understood in more detail from the following descriptions taken in conjunction with the accompanying drawings, in which:

FIG. 1 is a cross-sectional view of a semiconductor device according to an exemplary embodiment of the present invention;

FIG. 2 is a cross-sectional view of a semiconductor device according to an exemplary embodiment of the present invention;

FIGS. 3 to 10 are cross-sectional views illustrating a method of manufacturing a semiconductor device according to an exemplary embodiment of the present invention;

FIGS. 11 and 12 are cross-sectional views illustrating a method of manufacturing a semiconductor device according to an exemplary embodiment of the present invention;

FIGS. 13A and 13B are graphs showing measurement results of the threshold voltage and the carrier mobility of NMOS transistors; and

FIGS. 14A and 14B are graphs showing measurement results of the threshold voltages and the carrier mobilities of PMOS transistors.

### DESCRIPTION OF EXEMPLARY EMBODIMENTS

Exemplary embodiments of the present invention and methods of accomplishing the same may be understood more readily by reference to the following detailed description of exemplary embodiments and the accompanying drawings. The present invention may, however, be embodied in many different forms and should not be construed as being limited to the exemplary embodiments set forth herein. Rather, these exemplary embodiments are provided so that this disclosure will be thorough and complete and will fully convey the concept of the invention to those skilled in the art, and the present invention will only be defined by the appended claims. Like reference numerals refer to like elements throughout the specification.

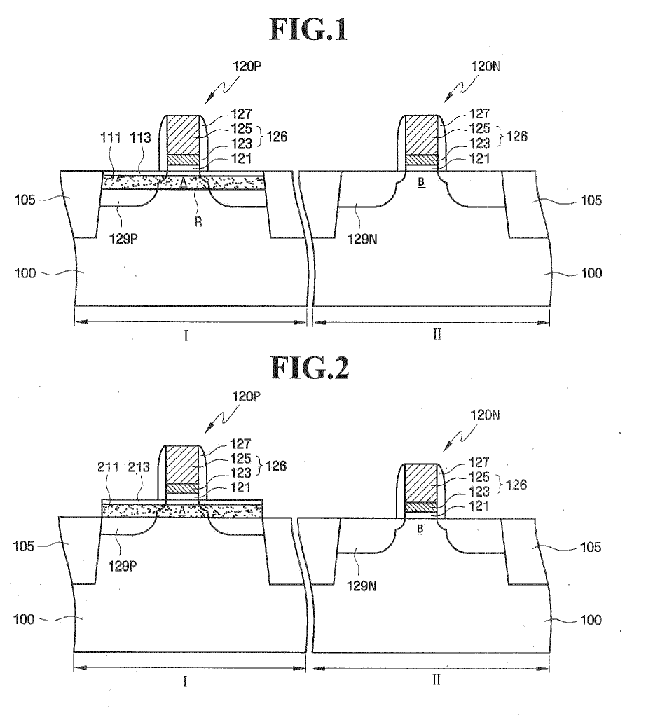

Hereinafter, a semiconductor device according to an exemplary embodiment of the present invention will be described with reference to FIG. 1. FIG. 1 is a cross-sectional view of a semiconductor device according to an exemplary embodiment of the present invention.

Referring to FIG. 1, the semiconductor device according to the exemplary embodiment of the present invention includes a semiconductor substrate 100 in which PMOS transistor regions I and NMOS transistor regions II are defined by element isolation films 105.

A substrate or SOI (Silicon On Insulator) substrate made of one or more semiconductor materials selected from a group consisting of Si, Ge, SiGe, GaP, GaAs, SiC, SiGeC, InAs, and InP may be used as the semiconductor substrate 100. The material used to form the substrate 100, however, is not limited to these materials.

A PMOS transistor 120P is formed in each PMOS transistor region I, and an NMOS transistor 120N is formed in each NMOS transistor region II.

The PMOS transistor 120P includes a gate electrode 126 that is formed on a high-dielectric gate insulating film 121 formed on an SiGe channel region A between P-type source and drain regions 129P.

According to the exemplary embodiment of the present invention, since the SiGe channel region A is used in the PMOS transistor 120P, it is possible to improve the carrier mobility of the PMOS transistor and to reduce the threshold voltage Vth of the PMOS transistor.

The conduction band offset of SiGe is lower than that of Si by about 30 mV, and the valence band offset of SiGe is lower than that of Si by about 230 mV. Accordingly, since the SiGe channel region A is used in the PMOS transistor 120P, it is possible to improve the threshold voltage characteristic of the PMOS transistor 120P.

In this exemplary embodiment, the SiGe channel region A may be formed in an SiGe epitaxial layer 111, and the SiGe epitaxial layer 111 may be formed in a recess R of the semiconductor substrate 100, as shown in FIG. 1. In this exemplary embodiment, the content of Ge may be about 10 to 40 at %. Further, an Si capping film 113 may be further formed on the SiGe channel region A. The Si capping film 113 may be formed of an Si epitaxial layer. The Si capping film 113 can improve the reliability of the gate insulating film 121 as compared to when the gate insulating film 121 is directly formed on the SiGe channel region A.

In this exemplary embodiment, the recess R of the semiconductor substrate 100 may be formed to have a depth of about 100 to 350 Å, and the SiGe epitaxial layer 111 fills the recess R and may be formed to have a thickness of about 100 to 300 Å. Further, the Si capping film 113 is formed on the SiGe epitaxial layer 111 so as to have a thickness of about 5 to 50 Å.

A high-dielectric film may be used as the gate insulating film 121. In this exemplary embodiment, the high-dielectric film means a film that is made of a material having a dielectric constant higher than a silicon oxide film, and is a film that is made of a material generally having a dielectric constant of 10 or more. For example, an oxide film, an aluminate film, a silicate film, or the like that contains at least one of the metals such as Hf, Zr, Al, Ti, La, Y, Gd, and Ta may be used as the high-dielectric film. The gate insulating film 121 may have a single layer structure or multilayer structure.

The thickness of the gate insulating film 121 may be in the range of about 10 to 60 Å, and the type and thickness of the gate insulating film may be changed without departing from the scope and spirit of the present invention.

Although not shown in the drawing, when the high-dielectric film is formed on the semiconductor substrate 100 so as to be used as the gate insulating film 121, a predetermined interface film (not shown) is further provided between the semiconductor substrate 100 and the gate insulating film 121 that is made of a high-dielectric material. The interface film improves the quality of the interface between the semiconductor substrate 100 and the gate insulating film 121, thereby improving the carrier mobility.

The gate electrode 126 may have a structure in which an upper gate electrode 125 is laminated on a lower gate electrode 123, but the structure of the gate electrode 126 is not limited to the above-mentioned structure. The lower gate electrode 123 serves as a barrier that prevents gate depletion from occurring when the upper gate electrode 125 is directly formed on the high-dielectric gate insulating film 121 or prevents dopants from entering from the polysilicon. Accordingly, the lower gate electrode 123 can prevent positive bias temperature instability (PBTI) from deteriorating, and improve the characteristic of the semiconductor device, and improve the electrical characteristic and reliability of the semiconductor device.

The lower gate electrode 123 may be made of a material that can prevent the dopants from being diffused in the upper gate electrode 125, which is formed on the lower gate electrode 123, and can suppress charge trapping. That is, the lower gate electrode 123 may be made of metal, metal nitride, or metal silicon nitride serving as the above-mentioned material. Further, the upper gate electrode 125 may be formed of a polysilicon film, a silicide film, or a laminated film formed by laminating the polysilicon film and the silicide film. The upper gate electrode 125, however, is not limited thereto. For example, the lower gate electrode 123 may be made of metal nitride, and the upper gate electrode 125 may be formed of a polysilicon film. Specifically, the lower gate electrode 123 may be formed of a nitride film that contains at least one of W, Mo, Ti, Ta, Al, Hf, and Zr, or a nitride film that includes metal containing at least one of W, Mo, Ti, Ta, Al, Hf and Zr, and Si or Al.

The NMOS transistor 120N includes a gate electrode 126 formed on the high-dielectric gate insulating film 121 that is formed on a Si channel region B between N-type source and drain regions 129N.

When the Si channel region B is used in the NMOS transistor 120N, it is possible to suppress of the diffusion of N-type dopants, such as As, as compared to when the SiGe channel region is used in the NMOS transistor. As a result, it is possible to reduce the deterioration of a short channel as compared to when the SiGe channel region is used in the NMOS transistor. For this reason, according to the exemplary embodiment of the present invention, the Si channel region B is used in the NMOS transistor 120N unlike the PMOS transistor 120P. Further, when the SiGe channel region is used in the NMOS transistor 120N, the carrier mobility deteriorates with no effect on the threshold voltage. Accordingly, unlike the PMOS transistor 120P, even though the Si channel region B is used in the NMOS transistor 120N, the threshold voltage can be maintained at an optimum level and the carrier mobility does not deteriorate. For this reason, it is advantageous to use the Si channel region B in the NMOS transistor 120N in terms of the characteristic of the semiconductor device.

The gate insulating film 121 may be formed of a high-dielectric film, as in the above-described PMOS transistor 120P. Further, the gate electrode 126 is also the same as in the PMOS transistor 120P. When a polysilicon film is formed in each of the gate electrodes of the PMOS transistor 120P and the NMOS transistor 120M and the type of polysilicon accords with the type of transistor, it is possible to obtain an advantageous characteristic of the semiconductor device. The present invention is not limited thereto, however, and the type of polysilicon does not need to accord with the type of the transistor.

As described above, the semiconductor device according to an exemplary embodiment of the present invention uses different channel regions depending on the types of the transistors. Accordingly, it is possible to improve the threshold voltage characteristic, that is, to maintain the absolute values of the NMOS transistors and the PMOS transistors at the same level. Further, since the deterioration of the short channel is suppressed, it is possible to improve the characteristic and reliability of the semi conductor device.

FIG. 2 is a cross-sectional view of a semiconductor device according to an exemplary embodiment of the present invention. The same components as those of the semiconductor device shown in FIG. 1 will be omitted or described in brief, and differences between the two exemplary embodiments will be mainly described below.

Referring to FIG. 2, the SiGe channel region A of the PMOS transistor 120P is formed in an SiGe epitaxial layer 211 that is formed on the semiconductor substrate 100. An Si capping film 213 may be formed on the SiGe epitaxial layer 211. As shown in FIG. 2, the PMOS transistor 120P may have a step so as to be higher than the NMOS transistor 120N.

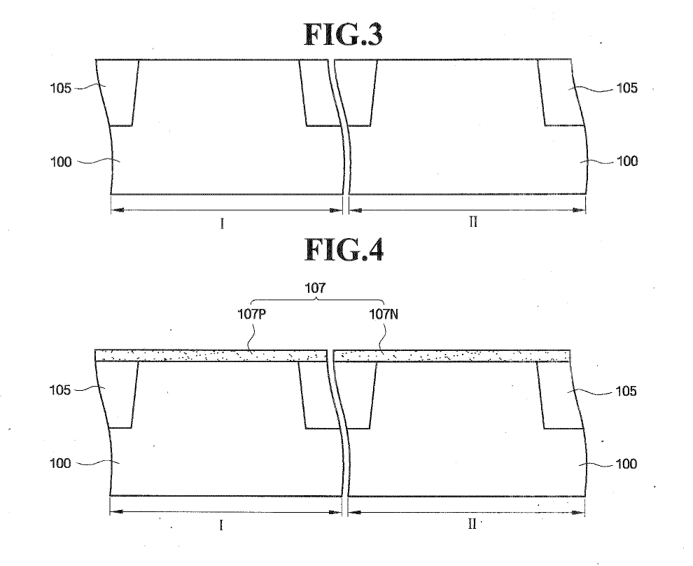

Hereinafter, an exemplary method of manufacturing the semiconductor device, which has been described with reference to FIG. 1, will be described with reference to FIGS. 3 to 10. FIGS. 3 to 10 are cross-sectional views illustrating a method of manufacturing the semiconductor device according to an exemplary embodiment of the present invention. In the following description of the method of manufacturing the semiconductor device, processes related to processes widely known to those of ordinary skill in the art of the present invention will be schematically described to avoid an ambiguous definition of the present invention. Further, substantially the same structure, material, and the like as those of the above-described semiconductor device will be omitted or described in brief to avoid repetition.

First, referring to FIG. 3, there is provided a semiconductor substrate 100 in which PMOS transistor regions I and NMOS transistor regions II are defined by element isolation films 105.

Each of the element isolation films 105 may be formed using a common STI (Shallow Trench Isolation) method. The method of forming the element isolation film, however, is not limited to the STI method. An insulating film, such as an HDP (High Density Plasma SiO₂) oxide film or an USG (Undoped Silicate Glass) film, may be used as each of the element isolation films 105. The element isolation film 105, however, is not limited to the above-mentioned insulating film.

As shown in FIG. 4, an epitaxial blocking film 107, which has an etching selectivity different from that of the element isolation film 105, is then formed on the semiconductor substrate 100.

The epitaxial blocking film 107 blocks a specific portion of the semiconductor substrate 100 in a selective epitaxy growth process so as to prevent an epitaxial layer from being formed at the specific portion on the semiconductor substrate 100. As long as the epitaxial blocking film 107 has an etching selectivity different from that of the element isolation film 105, there is no limitation in the type of the epitaxial blocking film 107 or a method of forming the epitaxial blocking film 107. In this exemplary embodiment, the epitaxial blocking film 107 may be an oxide film that is formed using an atomic layer deposition (ALD) method, a chemical vapor deposition method, or the like. The epitaxial blocking film 107 may be a silicon oxide film that is formed at a relatively low temperature by using the atomic layer deposition method. For example, the silicon oxide film to be used as the epitaxial blocking film 107 may be formed at a temperature of about 100 to 150° C. by using the atomic layer deposition method SiH₄, SiH₂Cl₂, SiHCl₃, SiCl₄, Si(OC₄H₉)₄, Si(OCH₃)₄, Si(OC₂H₅)₄, or the like may be used as a silicon source gas. The silicon source gas, however, is not limited thereto. Further, for example, H₂O, O₂, O₃, O radical, alcohol, H₂O₂ or the like may be used as an oxygen source gas. However, the oxygen source gas is not limited thereto.

The thickness of the epitaxial blocking film 107 may be in the range of about 30 to 300 Å, but is not limited thereto.

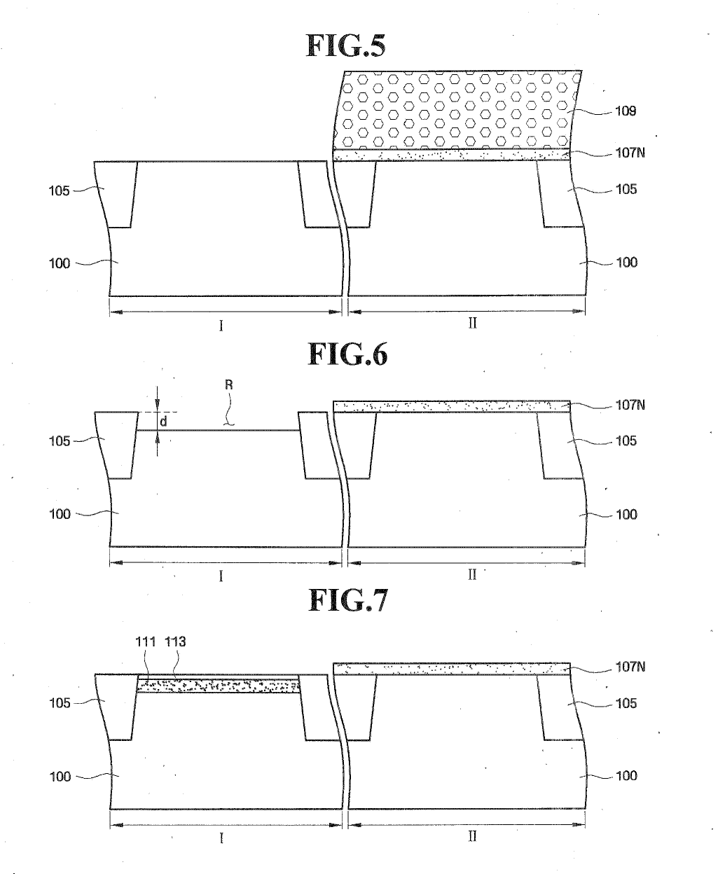

As shown in FIG. 5, the epitaxial blocking film 107P formed in the PMOS transistor region I is then selectively removed, so that the epitaxial blocking film 107N remains only in the NMOS transistor region II.

A mask pattern 109, for example, a photoresist pattern, which covers the NMOS transistor region II and exposes the PMOS transistor region I to the outside, may be formed to selectively remove the epitaxial blocking film 107P formed in the PMOS transistor region I. The mask pattern 109 may be removed using an etching process or an ashing process after a process for selectively removing the epitaxial blocking film 107P.

As described above, because the epitaxial blocking film 107 is made of a material having an etching selectivity different from that of the element isolation film 105, it is possible to selectively remove the epitaxial blocking film 107 with no effect on the element isolation film 105. For example, a silicon oxide film, which is formed by the above-mentioned atomic layer deposition method, can be removed using a diluted hydrofluoric acid solution. In this case, there is no effect on the element isolation film 105.

Next, as shown in FIG. 6, a recess R is formed on the semiconductor substrate 100 in the PMOS transistor region I.

Because the remaining epitaxial blocking film 107N can serve as an etch mask in the NMOS transistor region II, the recess R may be formed only in the PMOS transistor region I. The recess R may be formed by wet etching or dry etching that is used to selectively remove a part of the semiconductor substrate 100. A CDE (Chemical Dry Etching) may be used as the dry etching. For example, the CDE may be performed so that the amount of CF₄ and O₂ gas is adjusted to adjust the etching selectivity of the Si and SiO₂.

The recess R may be formed on the upper surface of the semiconductor substrate 100 so as to have a depth d of about 100 to 350 Å.

Referring to FIG. 7, an SiGe epitaxial layer 111 is formed in the recess R of the PMOS transistor region I by an SiGe epitaxy process.

An SiGe channel region A for a PMOS transistor may be formed in the SiGe epitaxial layer 111. Because the epitaxial blocking film 107 remains in the NMOS transistor region II, an epitaxial layer is not formed in the NMOS transistor region II by a selective epitaxy process.

The selective epitaxy process for forming the SiGe epitaxial layer 111 may be performed at a temperature of about 500 to 900° C. and at a pressure of about 1 to 500 Torr, and may be appropriately adjusted without departing from the scope and spirit of the present invention. Further, SiH₄, SiH₂Cl₂, SiHCl₄, SiCl₄, SiHₓCl_{y}(x+y=4), Si(OC₄H₉)₄, Si(OCH₃)₄, Si(OC₂H₅)₄ or the like may be used as the silicon source gas, and GeH₄, GeCl₄, GeHₓCl_{y}(x+y=4) or the like may be used as the Ge source gas. The silicon source gas and the Ge source gas, however, are not limited thereto. Furthermore, a gas such as HCl or Cl₂ may be added to the source gases to improve the selective characteristic. When HCl or the like is added to the source gases, it is possible to achieve the selective epitaxy growth. In the selective epitaxy growth, an epitaxial layer is not formed on the element isolation film 105 or the epitaxial blocking film 107N that is formed of an oxide film or a nitride film, but is formed on the semiconductor substrate, that is, in the region where Si is exposed to the outside. In this case, a dopant gas may be added to the source gases so as to provide dopants to the epitaxial layer. As described above, when the SiGe epitaxial layer is formed, the dopants may be doped by an in-situ process. The present invention, however, is not limited thereto. That is, after the SiGe epitaxial layer is formed, the dopants may also be doped by an ex-situ process.

According to an exemplary embodiment of the present invention, the content of Ge in the SiGe epitaxial layer 111 may be in the range of about 10 to 40 at % in consideration of the characteristic of the PMOS transistor. Further, the thickness of the SiGe epitaxial layer 111 may be in the range of about 100 to 300 Å. The selective epitaxy process has been widely known in the art, and the kinds and amounts of each of the source gases or added gases may be determined in consideration of the composition of the SiGe epitaxial layer to be formed, and the content of the dopants therein.

Subsequently, an Si capping film 113 may be further formed on the SiGe epitaxial layer 111. The Si capping film 113 may be selectively formed only on the SiGe epitaxial layer 111 by the selective epitaxy process.

The selective epitaxy process for forming the Si capping film 113 may be performed at a temperature of about 500 to 1000° C. and at a pressure of about 1 to 500 Torr, and may be appropriately adjusted without departing from the scope and spirit of the present invention. SiH₄, SiH₂Cl₂, SiHCl₃, SiCl₄, SiHₓCl_{y}(x+y=4), Si(OC₄H₉)₄, Si(OCH₃)₄, Si(OC₂H₅)₄ or the like may be used as the silicon source gas. Furthermore, a gas such as HCl or Cl₂ may be added to the source gas to improve the selective characteristic. When HCl is added to the source gases, it is possible to achieve the selective epitaxy growth in which an epitaxial layer is not formed on the element isolation film 105 or the epitaxial blocking film 107N that is formed of an oxide film or a nitride film. In this case, dopants for forming channels may be doped in the Si capping film 113. As described above, when the Si epitaxial layer is formed, the dopants may be doped by an in-situ process, however, the present invention is limited thereto. That is, after the Si epitaxial layer is formed, the dopants may also be doped by an ex-situ process.

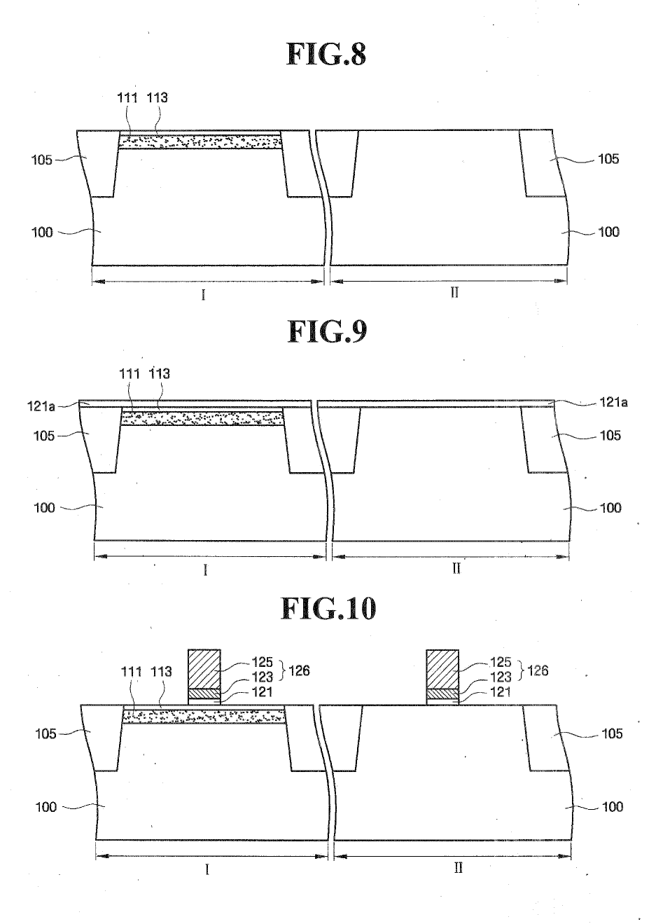

After that, as shown in FIG. 8, the epitaxial blocking film 107N remaining in the NMOS transistor region II is removed so as to expose a part of the semiconductor substrate, which corresponds to the NMOS transistor region II, to the outside.

The process for removing the epitaxial blocking film 107N remaining in the NMOS transistor region II is substantially the same as the process, which has been described with reference to FIG. 5, for removing the epitaxial blocking film 107P in the PMOS transistor region I. That is, it is possible to selectively remove only the epitaxial blocking film 107M with no effect on the element isolation film 105.

Subsequently, as shown in FIG. 9, a high-dielectric gate insulating film 121a is formed on the Si capping film 113 corresponding to the PMOS transistor region I and on the semiconductor substrate 100 corresponding to the PMOS transistor region I.

The gate insulating film 121a may be formed by the deposition of the material of the gate insulating film in the ALD or CVD process. In this case, the thickness of the gate insulating film 121a may be in the range of about 10 to 60 Å. Further, when a high-dielectric film is formed for use as the gate insulating film 121a, an interface film (not shown) may be further provided between the semiconductor substrate 100 and the gate insulating film 121a. The interface film can prevent a reaction from occurring between the high-dielectric film and the semiconductor substrate 100. The semiconductor substrate is cleaned using ozone water containing ozone gases or ozone, so that the thickness of the interface film is 1.5 nm or less.

After the deposition of the gate insulating film 121a, post deposition annealing (PDA) is performed so as to density the thin film. In this case, the PDA may be performed under an atmosphere, which includes at least one of N₂, NO, N₂O, O₂, and NH₃ gases, at a temperature of about 750 to 1050° C. The PDA may be appropriately adjusted depending on the kind or thickness of the thin film.

As shown in FIGS. 1 and 10, the PMOS transistor 120P is formed in the PMOS transistor region I, and the NMOS transistor 120N is formed in the NMOS transistor region II.

More specifically, as shown in FIG. 10, the gate electrode 126 is formed on each of the upper portions of the SiGe channel region A of the PMOS transistor region I and the Si channel region B of the NMOS transistor region II. Each of the gate electrodes 126 may be formed of the lower gate electrode 123 and the upper gate electrode 125. In particular, when the upper gate electrode 125 is formed of a polysilicon film, the same type of polysilicon film may be formed in the transistor regions so as to form the same type of gate electrodes. Alternative, a polysilicon film in which P-type dopants are doped may be formed in the PMOS transistor region I and a polysilicon film in which N-type dopants are doped may be formed in the NMOS transistor region II, so as to form different types of gate electrodes.

The P-type source and drain regions 129P are formed in the PMOS transistor region I and the N-type source and drain regions 129N are formed in the NMOS transistor region II. Accordingly, it is possible to completely form the PMOS transistor 120P and the NMOS transistor 120N, shown in FIG. 1. Reference numeral 127, which has not been described, indicates an insulating spacer.

In the following description of the exemplary method of manufacturing the semiconductor device, a process for forming wiring lines through which electrical signals are input and output, a process for forming a passivation layer on a substrate, and a process for packaging the substrate may be further performed in accordance with processes widely known to those of ordinary skill in the art of the semiconductor device, so as to completely form the semiconductor device. These succeeding processes will be schematically described to avoid any ambiguous definition of the present invention.

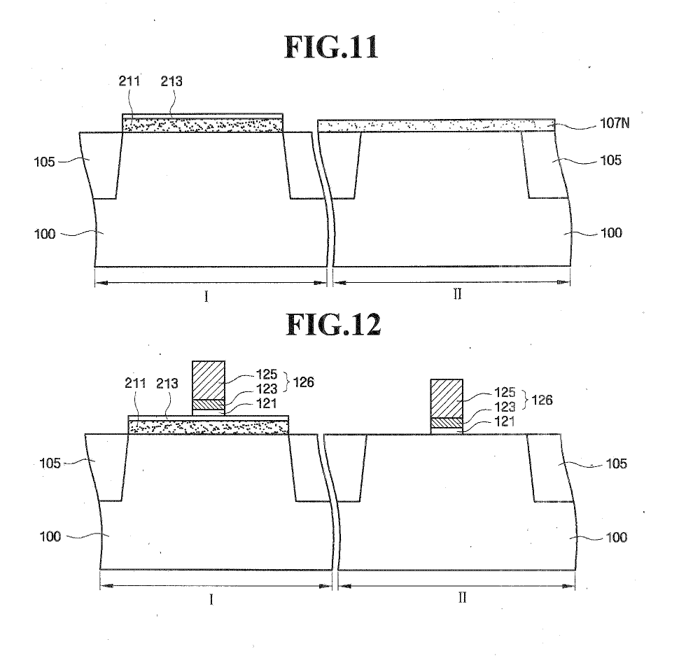

Hereinafter, an exemplary method of manufacturing the semiconductor device shown in FIG. 2 will be exemplarily described with reference to FIGS. 11 to 12. In the following description of the exemplary method of manufacturing the semiconductor device, processes related to processes widely known to those of ordinary skill in the art of the present invention will be schematically described to avoid any ambiguous definition of the present invention. Further, substantially the same structure, material, manufacturing process and the like as those of the above-described semiconductor device and the method of the semiconductor device described with reference to FIGS. 3 to 10 will be omitted or described in brief to avoid repetition, and differences between the above-described exemplary embodiments and another exemplary embodiment will be mainly described below. In addition, since the processes for manufacturing the semiconductor device described with reference to FIGS. 3 to 5 can be applied to this exemplary embodiment, only processes expanding on the processes described with reference to FIGS. 3 to 5 will be described below.

Referring to FIG. 11, the SiGe epitaxial layer 211 is selectively formed on the semiconductor substrate 100 corresponding to the PMOS transistor region I. In this exemplary embodiment, the recess R is not formed on the semiconductor substrate 100, and the SiGe epitaxial layer 211 may be formed so that the upper surface of the SiGe epitaxial layer 211 is higher than the upper surface of the semiconductor substrate 100.

Subsequently, the Si capping film 213 may be formed on the SiGe epitaxial layer 211 by the selective epitaxy growth process.

After that, the gate electrode 126 shown in FIG. 12 may be formed by substantially the same processes as the processes described with reference to FIGS. 8 to 10.

Subsequently, the insulating spacer 127, the P-type source and drain regions 129P, and the N-type source and drain regions 129N are formed so as to completely form the semiconductor device shown in FIG. 2.

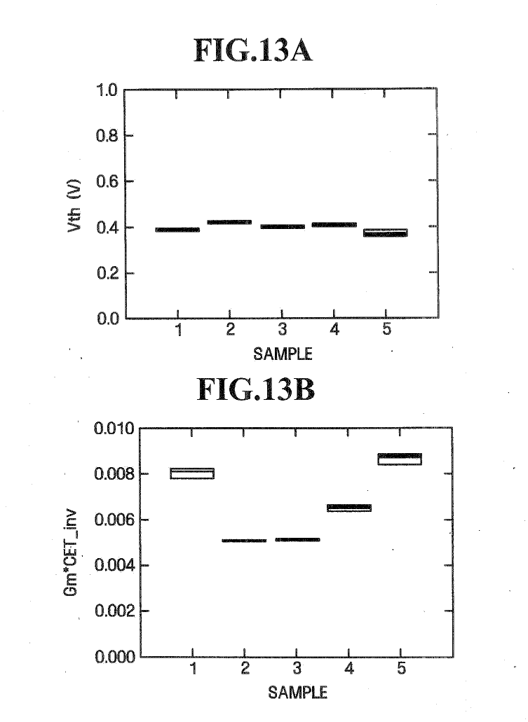

Hereinafter, the following test will be described with reference to FIGS. 13A and 13B. When the SiGe channel regions are used in the PMOS transistors and the NMOS transistors, the threshold voltage and carrier mobility are measured in the test. FIGS. 13A and 13B show measurement results of the threshold voltages and the carrier mobilities of the NMOS transistors.

Specifically, the NMOS transistors and the PMOS transistors are formed under the following conditions shown in the following Table 1, and the threshold voltages and the carrier mobilities are measured. An HfSiON film having a thickness of 30 Å is used as the gate insulating film. The ratio of width to length (W/L) is 1.0/1 μm, and a lower gate electrode formed of a TaN film and an upper gate electrode formed of a polysilicon film are laminated so as to be used as the gate electrode. An Si capping film is formed on the SiGe channel region.

TABLE 1

| | | | Si capping film |
|---|---|---|---|
| No | Type of transistors | Channel region | (Å) |
| Sample 1 | NMOS | Si | 0 |
| Sample 2 | | SiGe (150 Å) | 5 |
| Sample 3 | | SiGe (150 Å) | 10 |
| Sample 4 | | SiGe (150 Å) | 25 |
| Sample 5 | | SiGe (150 Å) | 50 |
| Sample 6 | PMOS | Si | 0 |
| Sample 7 | | SiGe (150 Å) | 5 |
| Sample 8 | | SiGe (150 Å) | 10 |
| Sample 9 | | SiGe (150 Å) | 25 |
| Sample 10 | | SiGe (150 Å) | 50 |

FIG. 13A is a graph showing measurement results of the threshold voltages of NMOS transistors corresponding to the samples 1 to 5, and FIG. 13B is a graph showing measurement results of the carrier mobilities of NMOS transistors corresponding to the samples 1 to 5.

Referring to FIG. 13A, it is understood that the threshold voltage of an NMOS transistor (sample 1) formed in an Si channel region is not significantly different from the threshold voltages of NMOS transistors (samples 2 to 5) formed in the SiGe channel regions. In contrast, referring to FIG. 13B, it is understood that the carrier mobilities of the NMOS transistors (samples 2 to 4) formed in the SiGe channel regions deteriorate as compared to the NMOS transistor (sample 1) formed in the Si channel region.

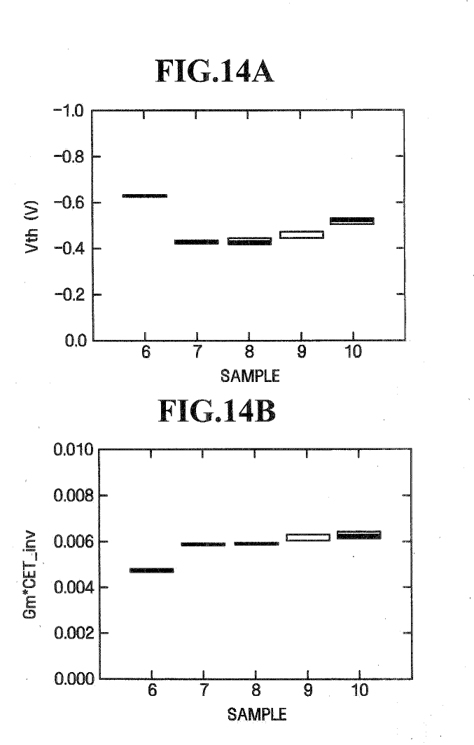

FIG. 14A is a graph showing measurement results of the threshold voltages of PMOS transistors corresponding to the samples 6 to 10, and FIG. 14B is a graph showing measurement results of the carrier mobilities of PMOS transistors also corresponding to the samples 6 to 10.

Referring to FIG. 14A, it is understood that the threshold voltages of PMOS transistors (samples 7 to 10) formed in the SiGe channel regions are lower than the threshold voltage of a PMOS transistor (sample 6) formed in an Si channel region. Further, referring to FIG. 14B, it is understood that the carrier mobilities of the PMOS transistors (samples 7 to 10) formed in the SiGe channel regions are improved as compared to the PMOS transistor (sample 6) formed in the Si channel region.

As described above, it is advantageous to apply the SiGe channel region to the PMOS transistor and to apply the Si channel region to the NMOS transistor, in terms of the threshold voltage or carrier mobility.

Although the present invention has been described in connection with the exemplary embodiments of the present invention, it will be apparent to those skilled in the art that various modifications and changes may be made thereto without departing from the scope and spirit of the present invention. Therefore, it should be understood that the above-described exemplary embodiments are not limitative, but illustrative in all aspects.

As described above, according to the semiconductor device of exemplary embodiments of the present invention, the PMOS transistor is formed in the SiGe channel region, and the NMOS transistor is formed in the Si channel region. Accordingly, it is possible to improve the characteristics of the semiconductor device, such as the threshold voltage and carrier mobility thereof.

What is claimed is:

1. A semiconductor device comprising:
a semiconductor substrate in which PMOS transistor regions and NMOS transistor regions are formed;
a PMOS transistor including P-type source and drain regions and a gate electrode, the PMOS transistor being formed in each PMOS transistor region, and the gate electrode being formed on a high-dielectric gate insulating film formed on an SiGe channel region between the P-type source and drain regions; and
a NMOS transistor formed on an Si channel region between N-type source and drain regions, the NMOS transistor including a high-dielectric gate insulating film and a gate electrode formed on the gate insulating film, the NMOS transistor being formed in each NMOS transistor region.

2. The semiconductor device of claim 1, wherein the SiGe channel region is formed in one of the semiconductor substrate and an SiGe epitaxial layer that is formed on the semiconductor substrate.

3. The semiconductor device of claim 1, wherein an Si capping film is interposed between the SiGe channel region and the gate insulating film.

4. The semiconductor device of claim 1, wherein the gate electrode comprises a lower gate electrode that comes in contact with the gate insulating film and is formed of one of metal nitride and metal silicon nitride, and an upper gate electrode that is formed on the lower gate electrode and is formed of a polysilicon film and/or a silicide film.

5. A method of manufacturing a semiconductor device, comprising:
providing a semiconductor substrate in which PMOS transistor regions and NMOS transistor regions are formed;
selectively forming an SiGe channel region in each PMOS transistor region;
forming a high-dielectric gate insulating film on the SiGe channel region corresponding to the PMOS transistor region and on the semiconductor substrate corresponding to the PMOS transistor region;
forming a PMOS transistor comprising a gate electrode and P-type source and drain regions on the SiGe channel region corresponding to the PMOS transistor region; and
forming a NMOS transistor comprising a gate electrode and N-type source and drain regions on an Si channel region corresponding to the NMOS transistor region.

6. The method of claim 5, wherein the step of forming the SiGe channel region comprises forming an epitaxial blocking film that selectively exposes the PMOS transistor region, and selectively forming an SiGe epitaxial layer in the PMOS transistor region.

7. The method of claim 6, wherein the step of forming the SiGe epitaxial layer comprises selectively forming the SiGe epitaxial layer in one of a recess region formed on the semiconductor substrate and on the semiconductor substrate.

8. The method of claim 5, further comprising;
forming an Si capping film between the SiGe channel region and the gate insulating film.

9. The method of claim 8, wherein the step of forming the Si capping film comprises forming an Si epitaxial layer on the SiGe channel region.

10. The method of claim 5, wherein the gate electrode comprises a lower gate electrode that comes in contact with the gate insulating film and is formed of one of metal nitride and metal silicon nitride, and an upper gate electrode that is formed on the lower gate electrode and is formed of a polysilicon film and/or a silicide film.

11. A method of manufacturing a semiconductor device, comprising:
providing a semiconductor substrate in which PMOS transistor regions and NMOS transistor regions are defined by element isolation films;
forming an epitaxial blocking film, which has an etching selectivity different from an etching selectivity of the element isolation film, on the semiconductor substrate;
selectively removing the epitaxial blocking film formed in the PMOS transistor region so that the epitaxial blocking film remains in only the NMOS transistor region;
forming an SiGe channel region on the PMOS transistor region by an SiGe epitaxy process;
removing the remaining epitaxial blocking film so as to expose the semiconductor substrate corresponding to the NMOS transistor region;
forming a high-dielectric gate insulating film on the Si capping film of the PMOS transistor region and on the semiconductor substrate corresponding to the PMOS transistor region;
forming a PMOS transistor comprising a gate electrode and P-type source and drain regions, on the SiGe channel region corresponding to the PMOS transistor region; and
forming an NMOS transistor comprising a gate electrode and N-type source and drain regions, on a Si channel region corresponding to the NMOS transistor region.

12. The method of claim 11, further comprising:
forming an Si capping film on the SiGe channel region by an Si epitaxy process.

13. The method of claim 11, wherein the step of forming the SiGe channel region comprises forming the SiGe epitaxial layer in one of a recess region formed on the semiconductor substrate or on the semi conductor substrate.

14. The method of claim 11, wherein the step of forming the epitaxial blocking film comprises forming a silicon oxide film on the semiconductor substrate by an atomic layer deposition method.

15. The method of claim 14, wherein the atomic layer deposition method is performed at a temperature range of 100 to 150° C.

16. The method of claim 11, wherein the step of selectively removing the epitaxial blocking film is performed by a wet etching using a hydrofluoric acid solution.

17. The method of claim 11, wherein the gate electrode comprises a lower gate electrode that comes in contact with the gate insulating film and is formed of one of metal nitride and metal silicon nitride, and an upper gate electrode that is formed on the lower gate electrode and is formed of a polysilicon film and/or a silicide film.
